(19) United States
(12) Patent Application Publication
(10) Pub. No.: US 2010/0046764 A1
(43) Pub. Date: Feb. 25, 2010

(54) Method and Apparatus for Detecting and Processing Audio Signal Energy Levels

(76) Inventor: Paul Wolff, Woodbridge, VA (US)

Correspondence Address: MCDERMOTT WILL & EMERY LLP, 2049 CENTURY PARK EAST, 38th Floor, LOS ANGELES, CA, 90067-3208, US

(21) Appl. No.: 12/196,146

(22) Filed: Aug. 21, 2008

(51) Int. Cl. H03G 3/20

(52) U.S. Cl. 381/57

(57) ABSTRACT

An audio signal processing circuit includes a variable gain control circuit controlled by a control signal; and an energy level detection circuit operable over the audio frequency spectrum for monitoring the audio input signal and producing the control signal. The control signal is adjustable in a manner to alter the energy of the audio input signal using the variable gain control device. The energy level detection circuit includes a variable filter configured to boost a first set of frequencies as compared to the second set of frequencies; and, a rectifier and an integrator connected in series or parallel, each having an input and an output, wherein the rectifier is operatively coupled to the variable filter and the integrator is coupled to the rectifier, and wherein the output from the integrator is used as the control signal to control the variable gain control device.

### BACKGROUND

I. Field

This application relates generally to audio level detection circuits for use in audio signal processing. More particularly, it concerns energy level detection method and apparatus that can preserve the tonal balance of an audio input signal by altering and detecting the spectral energy of the audio input signal over its dynamic frequency range and producing a gain control signal that is generally responsive to the high- and low-frequency components of the audio input signal according to the position of the control.

II. Background

Audio level detectors are typically used for adjusting the audio levels of an audio signal. Some prior art audio level detectors ignore the negative amplitude versus frequency slope that is a characteristic of all audio signals. The use of these audio level detectors does not allow an optimized application of audio level adjustment based on the specific type of program material. For example, audio program material containing speech should be processed differently than audio program material containing music. Other prior art audio level detectors limit the adjustability of the signal feeding the detector or completely eliminate any adjustment at all, greatly reducing the user's ability to adjust the audio to a point that is more desirable to the result that is being sought after.

Conventionally, an audio signal level detector simply rectifies an audio input signal and integrates, or smooths, the rectified output to produce a direct current (DC) gain control signal for use by a variable gain control device. The amplitude of the gain control signal is generally directly proportional, or fixed, at some preset curve over the audio frequency spectrum to the amplitude of the audio input signal. However, because of the characteristic nature of an audio input signal, in which lower frequencies tend to be of higher amplitude and higher frequencies tend to be of lower amplitude, the output of the variable gain device that processes the audio input signal is generally fixed at a level that has no real relationship to the actual dispersion of low and high frequencies. Since the dispersion depends on the type of program material, the fixed approach does not provide the flexibility to handle a variety of different types of programs.

It would be desirable to provide a variable audio signal energy level detection circuit that allows the operator to alter the tonal balance and timbre of an audio signal processed.

It is also desirable to provide a variable amplitude filter having a continuously adjustable positive or negative, amplitude versus frequency slope characteristic over an audio frequency range.

Preferably, the circuit may be provided in an easily manufactured configuration that contains a minimum of components.

Additionally, the adjustable energy level detection circuit may be straightforwardly incorporated into existing audio signal processing circuits and systems.

### SUMMARY

The following presents a simplified summary of one or more aspects in order to provide a basic understanding of such aspects. This summary is not an extensive overview of all contemplated aspects, and is intended to neither identify key nor critical elements of all aspects, nor delineate the scope of any or all aspects. Its sole purpose is to present some concepts of one or more aspects in a simplified form as a prelude to the more detailed description that is presented later.

According to various aspects, the subject innovation relates to systems and/or methods that provide the continuously adjustable response curve using a filter that is referred to as a “seesaw” filter, altered using a control that adjusts the low frequency to high frequency relationship much as the seesaw, (also known as a “teeter-totter”), alters the relationship between two parts (i.e., one part goes up as the other part goes down).

In one aspect, an audio signal processing circuit provides a continuously adjustable amplitude versus frequency slope for adjusting an audio input signal, the audio signal processing circuit having a variable gain control circuit controlled by a control signal; and an energy level detection circuit operable over the audio frequency spectrum for monitoring the audio input signal and producing the control signal, wherein the control signal is adjustable in a manner to alter the energy of the audio input signal using the variable gain control device. The energy level detection circuit includes a variable filter configured to alter a first and second set of frequencies such that the first set of frequencies is boosted as compared to the second set of frequencies; and, a rectifier and an integrator connected in series or parallel, or any combination of the two, each having an input and an output, wherein the input of the rectifier is operatively coupled to the variable filter and the input of the integrator is operatively coupled to the output of the rectifier, and wherein the output from the integrator is used as the control signal to control the variable gain control device.

In another aspect, a method for continuously adjusting an amplitude versus frequency slope for an audio input signal is implemented that includes controlling a variable gain control circuit, wherein the variable gain control circuit is controlled by a control signal; monitoring the audio input signal over an audio frequency spectrum to produce the control signal; and adjusting the control signal in a manner to alter the energy of the audio input signal via the variable gain control device. The adjustment of the control signal includes altering a first and second set of frequencies using a filter such that the first set of frequencies is boosted as compared to the second set of frequencies; rectifying the audio input signal to create a rectified control signal; and integrating the rectified control signal to control the variable gain control device.

### BRIEF DESCRIPTION OF THE DRAWINGS

FIG. 1 and FIG. 2 are block diagrams of a prior art circuit that features amplitude level detection and fixed filtering.

FIG. 3 and FIG. 4 are block diagrams of the apparatus of the invention in its preferred embodiment, as used in audio signal processing, showing both series and parallel use.

FIG. 5 is a detailed schematic diagram of a passive embodiment of the adjustable filter shown in FIG. 3 and FIG. 4.

### DETAILED DESCRIPTION OF THE PREFERRED EMBODIMENTS

The invention in its preferred embodiment comprises an audio input signal terminal having series-connected thereto dual Baxandall (or similar shelving type equalization circuit, not limited to the single pole characteristics of the Baxandall filter) adjustable low and high frequency filter, both contained on the same control, but working on opposing directions, which is referred to as a seesaw filter, when rotated and a rectifier the output of which is connectable to the control input of a variable gain device through which the audio signal may be processed. The beneficial result of adjustable seesaw filtering of the audio input signal before rectification (and smoothing) is that a control signal having an amplitude that is adjustable allowing the operator virtually an infinite choice of setting for said device.

An audio signal energy level detector for use with audio signal processing system is described. The audio signal energy level detector is implemented in a side-chain of an audio signal processing circuit to control the processing of an input audio signal. The audio signal energy level detector includes a seesaw-type equalizer system that receives the audio input signal and adjusts the ratio of low frequency energy to the high frequency energy before feeding the adjusted signal to a series or parallel connected rectifier and simple integrator to generate an output signal. The output from the rectifier/integrator circuit controls a Voltage Controlled Gain Device (VCGD) that processes the audio input signal. This function, along with many of the other audio processing functions, may also be implemented using a software DSP format.

In one aspect, the adjustable control system includes an adjustable Baxandall-based or similar type of filtering system that can be controllable to simultaneously alter the bass and treble portions of the audio input signal. The control interface may be a knob or dial or other remote controlled or software controlled device, which will be referred to as the “knob”. The knob is reversed with respect to one of the controls, where turning in one direction—the right, for example—results in a boost of high frequencies while simultaneously decrease the low frequencies, and turning in the opposing direction provides an opposite result, where the low frequencies are boosted while the high frequencies are cut. It should be appreciated that the direction of the rotation and type of specific control interface are not important, just that the control allows the boost of one set of frequencies while reducing the other to result in an altered signal. The resulting altered signal is then fed into the rectifier, which turns the alternating current audio signal into a direct current signal embodying peak and/or Root-Mean-Squared (RMS) characteristics of the altered audio signal having a control voltage form.

Consequently, when the audio input signal is processed by the adjustable seesaw based filtering system, a control voltage can then be altered to represent a more high frequency energy based control voltage or a more low frequency based control voltage. This variable control is very important when being fed into the VCGD, as the perceived loudness of the original audio signal can be altered and, depending on the position of the control, can be less or more noticeable to the listener. The dynamics (the relationship between quiet and loud passages) of the input audio signal may thus be adjusted to sound unaltered to an untrained ear, which is one possible and desirable effect.

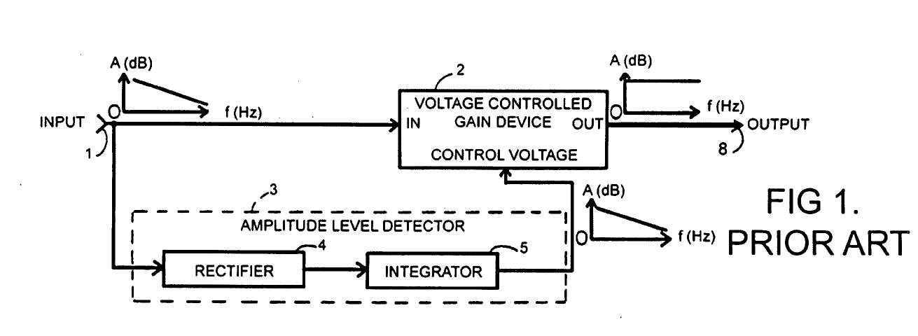

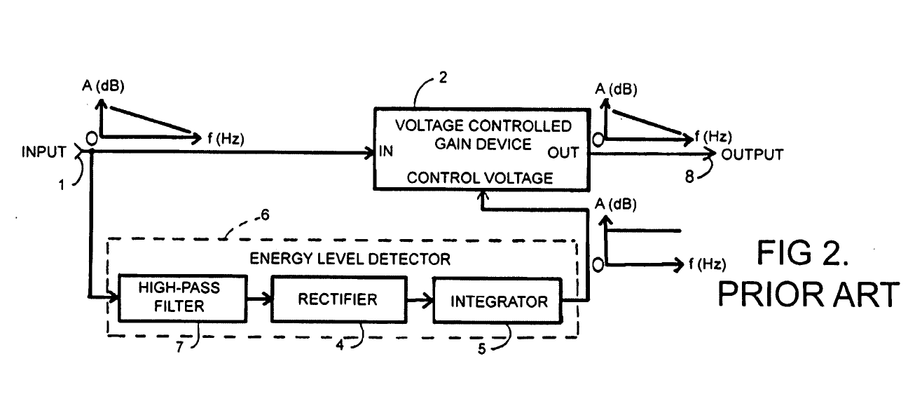

Referring collectively to FIGS. 1 and 2, it will be appreciated that the block diagrams and circuits are appended by graphs that show the amplitude versus frequency characteristics of various signals. The graphs show (logarithmically scaled) frequency in hertz (Hz) along the abscissa and relative amplitude (A) in decibels (db) along the ordinate. The origins (“0”) of the graphs are labeled, and represent 0-Hz and 0-db. The graphs illustrate the characteristic slopes of the signal/response curves associated with various parts of the block diagrams and circuits and demonstrate the differences between other audio signal processing circuits.

Referring first to FIG. 1, a prior art audio signal processing circuit is shown in block diagram form. It includes an audio input signal connected to an input terminal 1 connected, in turn, to the input (IN) of a voltage controlled gain device 2 the output (OUT) of which is connected to an output terminal 3. It should be appreciated that voltage controlled gain device 2 is conventional. It is sufficient to say that voltage controlled gain device 2 produces an output (OUT) signal that is a function of its input (IN) signal, with the gain, which may be positive or negative, controlled by its control (CONTROL VOLTAGE) input. In one exemplary mode of operation, with a positive control input, voltage controlled gain device 2 would operate to increase the audio input signal present at input terminal 1. In another exemplary mode of operation, with a negative control input, voltage controlled gain device 2 would operate to reduce the audio input signal at input terminal 1. By use of the circuit illustrated in FIG. 1, along with downstream audio signal processing circuitry or equipment, a variety of dynamic audio effects can be produced, e.g., signal compression, expansion, ducking, limiting, noise gating, automatic gain control (AGC), among others.

One circuit conventionally used to control a variable gain device is an amplitude level detector 3. Amplitude level detector 3 includes a rectifier 4, which produces a DC output signal that is proportional to the amplitude of the alternating audio input signal impressed on input terminal 1. Connected in series with rectifier 4 is an integrator 5, which integrates, or smooths, the DC output signal from rectifier 4 to produce a result of the signal that can be adjusted (not shown) to be smooth or can follow the dynamics of the input terminal 1.

Amplitude level detector 3 is so called because (as illustrated by the graph nearest its output signal) it produces an output signal over the audio frequency range that is directly proportional to the amplitude of the audio input signal at input terminal 1 (as shown nearest input terminal 1 in FIG. 1), which audio input signal may be seen to have a falling dB/decade amplitude versus frequency slope that is characteristic of audio signals over the audio frequency range. Notably, the output (OUT) signal from voltage controlled gain device 2 under control of amplitude level detector 3 has a near constant amplitude over the audio frequency range (as shown graphically nearest the output of voltage controlled gain device 2 in FIG. 1. Thus, in previous systems, amplitude level detectors, the output signal from a variable gain device controlled thereby exhibits a shift of the tonal balance and a reduction of the dynamics of an audio signal processed therethrough, i.e., because of the energy relationship of low frequencies vs. high frequencies, where the energy in the low frequencies are much greater, the control voltage is largely made up of the low frequency energy, “ignoring” the useful portion of the high frequencies as a reference and generating element in the control voltage.

Turning now to FIG. 2, current implementations use an “equal energy per octave” high-pass filter 7 that attempts to match the control voltage dynamic response to the actual redistributed energy of the audio signal, which distributes the source of the control voltage evenly over the entire audio spectrum. It will be understood that for practical purposes, the functional blocks of FIG. 2 are identical with those of FIG. 1 that are identically designated, i.e., input terminal 1, voltage controlled gain device 2, output terminal 8, rectifier 4 and integrator 5 are conventional. Importantly, the previous implementation includes an audio input signal energy level detector 6 interposed between input terminal 1 and the control (control voltage) input of voltage controlled gain device 2. Audio input signal energy level detector 6 includes a high-pass input filter 7 that is directly operatively connected to an audio input signal impressed on input terminal 1 and is before rectifier 4. In an exemplary approach the high-pass input filter 7 is a filter having a predefined characteristic of being dynamically responsive to higher audio frequencies than to lower audio frequencies. In response to the audio input signal, high-pass filter 7 produces a filtered audio signal that is generally constant over the audio frequency range. Energy level detector 6 also includes level detection means—including rectifier 4, which includes signal smoothing means, or integrator, 5, operatively connected to input filter 7 and which is responsive to the filtered audio signal, for detecting the energy level in the filtered audio signal to produce a control signal proportional thereto, thereby to control an audio signal processor downstream from such audio input signal.

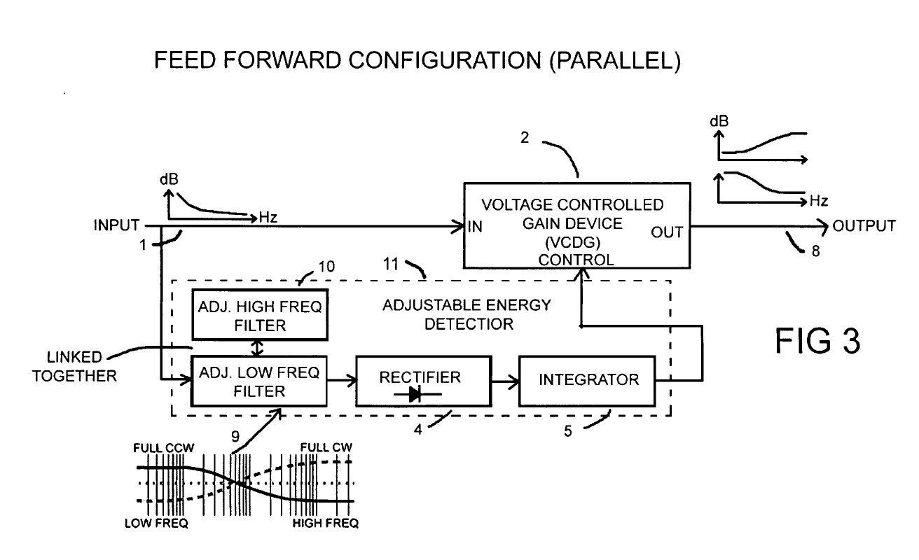

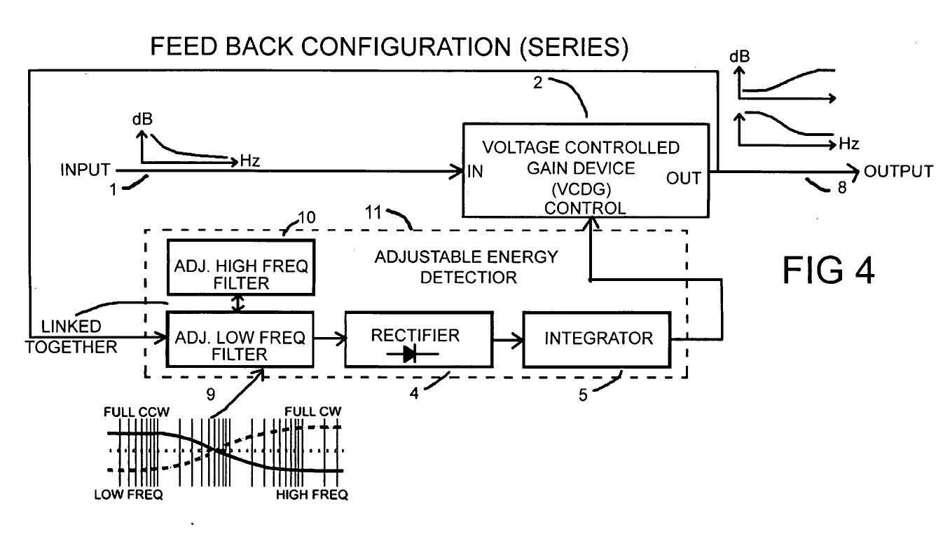

FIGS. 3 and 4 are a block diagram of preferred embodiments of the exemplary circuit. FIG. 3 shows a feed forward (parallel) configuration, and FIG. 4 shows a feedback (series) configuration. Within the exemplary system is as an adjustable audio signal level detection circuit. The level detection circuit includes audio input signal terminal 1, a unique adjustable energy detector 11 including means for rectifying a signal input thereto via input terminal 1 and smoothing the rectified output thereof to produce an adjustable DC output signal representing the approximate amplitude of the signal input thereto. In the exemplary system the means for rectifying and smoothing a signal input are implemented using a rectifier 4 and an integrator 5, respectively. With the exemplary system, the level detection circuit also includes an adjustable high frequency and low frequency filter, linked together and, depending on the mode of operation within the device, can be operatively connected between audio input signal terminal 1 and detector 11 or can be fed from the output 8 to the input of the detector 11. The audio signal level detection circuit can thereby adjust continuously the amplitude of the energy in the high frequencies or in the low frequencies, increasing or decreasing the amplitude of the lower frequency components relative to the higher frequency components, and visa-versa, of the audio input signal impressed on input signal terminal 1.

Yet another way of operating the audio signal energy level detection and processing approach and system is as an audio signal energy level detector for use with a variable gain device having input and control terminals. The adjustable energy detector 11 includes a filter similar to a bass and treble control used on a HI-FI system, where the bass control is reversed, so clockwise rotation reduces the bass and the treble control is left alone, but attached to the same control. Rotating the control clockwise then increases the high frequencies while reducing the low frequencies. The direction of rotation is irrelevant and may be implemented using various other mechanisms (e.g., sliders), and use of the rotation approach is only one way in which the adjustable control may be implemented. The resulting output from the adjustable filter 10, responsive to an audio input signal impressed upon input terminal 10, the filter means having a continuously adjustable response (e.g., that shown graphically nearest the adjustable filter 10 by the graph labeled 9 in FIG. 3 and FIG. 4) that attenuates low-frequency spectral components while boosting the high frequency spectral component when rotated in one direction and attenuates high frequency spectral components while boosting the low frequency spectral component when rotated in the other direction. The resulting output is shown graphically nearest output 8 (e.g., signal terminal in FIG. 3 and FIG. 4). The energy level detector also includes rectifier means, or at least rectifier 4, and optionally and preferably also integrator 5, responsive to the generally level output signal of the filter means to produce a control signal for connection with a control terminal of voltage controlled gain device 2, for processing the audio input signal at the input terminal of voltage controlled gain device 2, thereby to produce a gain-controlled audio output signal at output signal terminal 3 for further downstream processing.

It should be appreciated that the audio signal energy level detection and processing approach and system as embodied by the exemplary embodiments described herein represents a significant improvement over conventional audio input signal level detectors. Conventional audio signal processing circuits for processing an audio input signal having a predefined amplitude versus frequency slope, include a variable gain control device controlled by a control signal produced by a series-connected rectifier an input of which is connected to an audio input signal terminal and an integrator an input of which is the rectified output of the rectifier. Such a circuit configuration, e.g., that shown in FIG. 1, achieves amplitude level detection and can suffer an often undesirable shift in the tonal balance of the audio input signal. The circuit configuration in FIG. 2 allows for a fixed adjustment of this rectified output, with no adjustable component, limiting its uses.

The exemplary embodiments, which constitutes an improvement over conventional audio signal processing circuits, accomplishes an adjustable energy level detection for purposes of controlling the conventional variable gain device by the interposition of the seesaw-type adjustable energy filter 11 between the audio input signal input terminal 1 and the input of rectifier 4, or between the signal output 8 and the input of the rectifier 4. Preferably, the seesaw-type adjustable filter 10 provides a continuously adjustable control that can adjust for a more pleasing smooth signal result, or it can be adjusted for extreme results that may lent itself as more of an effect rather than a more pleasing result. Thus, the exemplary embodiments can preserve the tonal balance and timbre of the audio input signal or it can greatly alter it for further downstream processing.

The preferred audio signal processing approach of the various possible embodiments may now be understood in view of the above description of the preferred embodiment. The preferred approach includes: 1) impressing on an input terminal, e.g., input terminal 1, an audio input signal feeding the continuously adjustable filter, e.g., via adjustable filter 10, the audio input signal impressed on the input terminal, thereby producing a filtered audio signal having a continuously adjustable low-frequency and high-frequency components; and 3) rectifying, e.g., via rectifier 4, the filtered audio signal to produce a DC control signal directly proportional to the filtered audio signal (as shown graphically nearest the output of adjustable energy level detector 11 in FIG. 3 and FIG. 4), the control signal being connectable to a control input of a variable gain device, e.g., voltage controlled gain device 2, for processing the audio input signal, thereby to produce on an output terminal, e.g., output terminal 8, for further downstream audio signal processing a modified audio output signal in such manner that the user can alter the result in a way the is desirable. It should be appreciated that the rectifying step preferably includes smoothing the rectified output, e.g., via integrator 5 (which may be integral with rectifier) to produce the control signal that is connectable to the control input of the variable gain device.

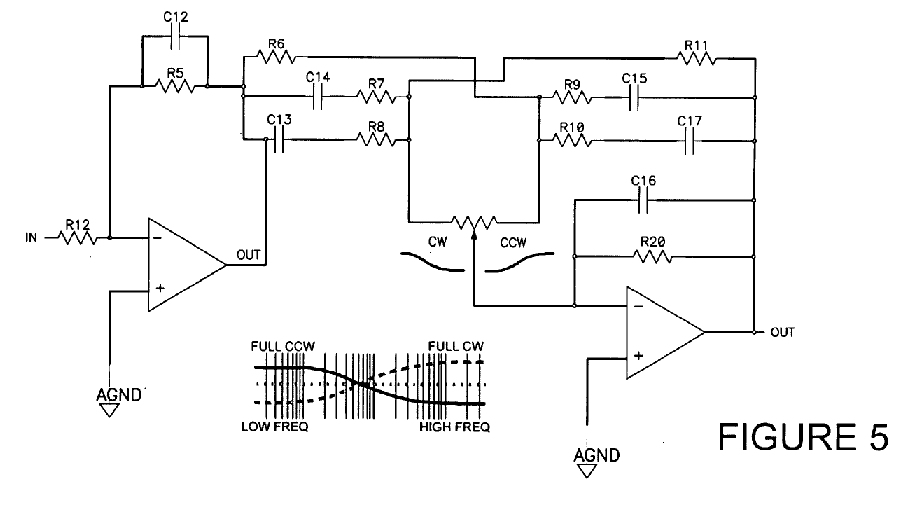

Referring next to FIG. 5, a schematic diagram of the adjustable filter 10 in a preferred embodiment is shown. The adjustable filter 10 shows clearly the exemplary components that may be used to implement the exemplary approaches described herein, and that the exact component values are not a critical part of the description, where alteration of the specific center frequency or boost and cut decibel levels are not critical to the description.

It should be appreciated that, within the spirit of the exemplary embodiments disclosed herein, the adjustable filter 10 may have an adjustable amplitude versus frequency slope that is only nominally, rather than precisely, defined and may operate over a different frequency range; may utilize different circuit elements; and/or may be of an different circuit topology than that illustrated herein. Those of skill also will appreciate that the adjustable energy detector 11 may use an alternative detection scheme and/or circuit topology, so long as it has an adjustable filter capable of advantageously modifying the amplitude versus frequency characteristics of the audio input signal, prior to detection or rectification. It is this continuously adjustable filtration that results in a variable energy level detection rather than a fixed level detection, which can be adjusted from an amplitude based level detection, to an energy level detection, to an inverse energy level detection, depending on the position of the control.

In one aspect, the circuits herein are used to improve the quality of the audio signal sis used to create an effect, where a signal is altered in such a way that the desired effect may not be an “improvement” of the sound, but a purposeful distortion of the sound to create a different sound that is more desirable for the a particular application.

Additionally, with the relatively recent development of computer-based audio processing equipment, many of the analog- or component-based designs can be modeled or simulated in the digital domain using a computer with what is referred to as a digital equivalent of the circuit, and the digital equivalent then used within the digital domain to copy or simulate the same features in analog or component based forms.

Accordingly, although preferred and alternative preferred embodiments of the invention, as well as a preferred method of practicing it, have been described, it should be appreciated that modifications may be made thereto without departing from the scope of the system as defined in the appended claims.

What is claimed is:

1. An audio signal processing circuit providing a continuously adjustable amplitude versus frequency slope for adjusting an audio input signal, the audio signal processing circuit comprising:
a variable gain control circuit controlled by a control signal; and
an energy level detection circuit operable over the audio frequency spectrum for monitoring the audio input signal and producing the control signal, wherein the control signal is adjustable in a manner to alter the energy of the audio input signal using the variable gain control circuit, said energy level detection circuit comprising:
a variable filter configured to alter a first and second set of frequencies such that the first set of frequencies is boosted as compared to the second set of frequencies; and,
a rectifier and an integrator connected in series or parallel, or any combination of the two, each having an input and an output, wherein the input of the rectifier is operatively coupled to the variable filter and the input of the integrator is operatively coupled to the output of the rectifier, and wherein the output from the integrator is used as the control signal to control the variable gain control circuit.

2. The audio signal processing circuit of claim 1, further comprising a continuously adjustable control, wherein the continuously adjustable control alters the variable filter along a continuum of settings.

3. The audio signal processing circuit of claim 1, wherein the control signal adjustment manner is chosen so that the audio signal is processed in a way that improves the sound quality of the audio input signal.

4. The audio signal processing circuit of claim 1, wherein the control signal adjustment manner is chosen so that the audio signal is processed to add an effect to the audio input signal. The audio signal processing circuit of claim 1, wherein the filter is comprised of a Baxandall-type filter.

6. The audio signal processing circuit of claim 5, wherein the Baxandall-type filter is comprised of a single order Baxandall-type filter.

7. The audio signal processing circuit of claim 1, wherein the first set of frequencies is higher than the second set of frequencies.

8. The audio signal processing circuit of claim 7, wherein the second set of frequencies ranges from approximately 20 Hertz to a center-point frequency.

9. The audio signal processing circuit of claim 8, wherein the center-point frequency is in an approximate range of 100-1,500 Hertz.

10. The audio signal processing circuit of claim 7, wherein the first set of frequencies ranges from a center point frequency to an upper frequency limit that is higher than the center point frequency.

11. The audio signal processing circuit of claim 10, wherein the center-point frequency is in an approximate range of 100-1,500 Hertz.

12. A method for continuously adjusting an amplitude versus frequency slope for an audio input signal comprising:
controlling a variable gain control circuit, wherein the variable gain control circuit is controlled by a control signal;
monitoring the audio input signal over an audio frequency spectrum to produce the control signal; and
adjusting the control signal in a manner to alter the energy of the audio input signal via the variable gain control circuit, the adjustment of the control signal comprising:
altering a first and second set of frequencies using a filter such that the first set of frequencies is boosted as compared to the second set of frequencies;
rectifying the audio input signal to create a rectified control signal; and
integrating the rectified control signal to control the variable gain control circuit.

13. The method of claim 12, wherein controlling the variable gain control circuit comprises adjusting the variable gain control circuit using a continuously variable control.

14. The method of claim 12, wherein the control signal adjustment manner is chosen so that the audio signal is processed in a way that improves the sound quality of the audio input signal.

15. The method of claim 12, wherein the control signal adjustment manner is chosen so that the audio signal is processed to add an effect to the audio input signal. The method of claim 12, wherein the filter is comprised of a Baxandall-type filter.

17. The method of claim 16, wherein the Baxandall-type filter is comprised of a single order Baxandall-type filter.

18. The method of claim 12, wherein the first set of frequencies is higher than the second set of frequencies.

19. The method of claim 12, wherein the second set of frequencies ranges from approximately 20 Hertz to a center-point frequency.

20. The method of claim 19, wherein the center-point frequency is in an approximate range of 100-1,500 Hertz.

21. The method of claim 12, wherein the first set of frequencies ranges from a center point frequency to an upper frequency limit that is higher than the center point frequency.

22. The method of claim 21, wherein the center-point frequency is in an approximate range of 100-1,500 Hertz.

23. An audio signal processing circuit comprising:
variable gain control means controlled by a control signal; and
energy level detection means for monitoring an audio input signal;
rectifier means coupled to the energy level detection means; and
integrator means coupled to the rectifier means, wherein the output from the integrator is used as the control signal to control the variable gain control means.
